(19) United States
(12) Patent Application Publication
(10) Pub. No.: US 2026/0318847 A1
(43) Pub. Date: Oct. 15, 2026

(54) Device and Method for Inspection of a Substantially Transparent Substrate

(71) Applicant: Morphotonics Holding B.V., Veldhoven (NL)

(72) Inventors: Leon Willem Veldhuizen, Veldhoven (NL); Jan Matthijs Ter Meulen, Veldhoven (NL)

(21) Appl. No.: 19/484,414

(22) PCT Filed: May 16, 2024
(86) PCT No.: PCT/NL2024/050246

§ 371 Date: Nov. 14, 2025

(30) Foreign Application Priority Data
May 17, 2023 (NL) 2034855

(51) Int. Cl. G01N 21/958; G01N 21/896

(52) U.S. Cl. CPC G01N 21/958; G01N 21/896; G01N 2021/8965

(57) ABSTRACT

The invention relates to a device and a method for enabling inspection of a substantially transparent substrate. The device includes a housing and a light source, and method enables analyzing of a substantially transparent substrate positioned within the housing in an effective manner.

### CROSS-REFERENCE TO RELATED APPLICATIONS

This application is the United States national phase of International Patent Application No. PCT/NL2024/050246 filed May 16, 2024, and claims priority to The Netherlands Patent Application No. 2034855 filed May 17, 2023, the disclosures of which are hereby incorporated by reference in their entireties.

### BACKGROUND OF THE INVENTION

### Field of the Invention

The invention relates to a device for enabling inspection of a substantially transparent substrate. The invention also relates to an assembly of such device and at least one imaging device and to an imprinting system comprising such assembly. The invention further relates to a method for inspection of a substantially transparent substrate.

### Description of Related Art

Determining defects in micro-and nanostructures is a challenge, in particular when the defects are to be determined over a large surface. In the technical field of imprinting, in particular nanoimprinting, it is essential that produced products have a consistent quality which fulfils high quality standards. Maintaining a constant quality requires continuous quality control during or after each step of the production process. An example of an overall imprinting process is a sequence wherein the texture of a master is transferred to a stamp, and wherein said stamp, or an assembly of stamps formed by the master, subsequently transfers the texture to a product. Hence, in each case, a texture is transferred from substrate to substrate. In case there is a defect in the surface of master, this will be transferred to the stamp too. The same applies for the transfer from stamp to product, where also the texture including any defects will be transferred in case the stamp contains an imperfection or deficiency. It is desired to be able to determine and classify any imperfections of the stamp, master and/or final product in order to check and control the quality of the process.

### SUMMARY OF THE INVENTION

It is therefore a goal of the invention to provide a device and method wherein quality control of a substrate, in particular a transparent substrate, is enabled in a relatively simple but effective manner.

The invention provides thereto a device configured for enabling inspection of a substantially transparent substrate, comprising:
at least one housing configured for receiving at least one substantially transparent substrate, said housing comprising:
   optionally at least one edge configured for surrounding and/or enclosing at least part of the substrate;
   at least one support surface configured for supporting at least part of the substrate; and
   optionally at least one back cover configured for covering at least part of the substrate;
at least one light source configured for illumination at least part of the substrate; wherein at least one light source is positioned at least partially within the housing such that at least one light source is directed to at least one edge and/or side edge of the substrate which is received within the housing, in particular such that at least part of the light emitted by at least one light source enters the substrate via at least one side edge such that the light can propagate through the substrate.

The device according to the present invention enables inspection of a substantially transparent substrate in an effective and controlled manner. The device according the invention enables that at least one substrate, preferably a substantially transparent substrate, can be positioned upon at least one support surface of a housing, whilst the substrate is at least partially surrounded by at least one edge of said housing and also at least partially covered by at least one back cover. The device is in particular configured for determining defects in at least one substrate prior to nanoimprinting and/or for determining defected in a nanoimprinted substrate. The housing thereby substantially forms a frame wherein the substrate is received. This results in that the substrate is substantially received within the housing in a non-destructive manner. The clever positioning of at least one light source, wherein said at least one light source is positioned at least partially within the housing such that said light source is directed to at least one edge and/or side edge of the substrate which is received within the housing, enables that the substrate can be illuminated from a side edge, or sideways. At least one light source is particular positioned such that at least part of the light emitted by the at least one light source enters the substrate via at least one side edge such that the light can propagate through the substrate. Hence, light enters the substantially transparent substrate via at least one side edge and is propagating through the substrate by total internal reflection. When subsequently imagines of the illuminated substrate are taken with an imaging device, such as a camera, the images can be analyzed for any defects and/or irregularities. Illuminating at least one edge, and in particular at least one side edge, of at least one substantially transparent substrate results in that any light scattering elements present in or upon the substrate that distort the total internal reflection can be detected in an efficient and effective manner. Irregularities or defects inside or upon the surface of the substrate will scatter at least part of the light emitted by the light source(s) which will cause detectable peaks in the image made of the illuminated substrate. It was experimentally found that the results are more reliable and detailed when using a substrate which is illuminated from a side edge than when the surface which is to be analyzed is illuminated from an angle, for example from a front side or under an angle (e.g. by using shearing of light).

At least one housing is in particular configured for receiving at least one substrate. Hence, at least one substrate can be retained by at least one housing. The housing provides thereby a supportive and protective function for the substrate. When it is referred to a housing, also a frame can be meant. The housing can for example comprise at least one receiving space for receiving at least one substrate, preferably at least one substantially transparent substrate. The housing may also define at least one receiving space. It is for example imaginable that at least one receiving space is defined by at least one support surface and at least one edge of the housing. At least one light source may be received within the receiving space. The housing, or frame, can be configured to at least partially surround the substrate. At least one support surface is preferably configured such that at least one substrate can be positioned upon at least part of the support surface. The support surface thereby provides a supportive function for the substrate. It is imaginable that the support surface is configured to support at least one substrate via at least part of its circumference. In this way, the support surface will not negatively affect the illumination and/or imaging process. It is for example imaginable that at least one support surface is configured for supporting part of an outer surface of the substrate. Preferably, at least one support surface is positioned such that a central area of the substrate is free of any support.

When it is referred to a substantially transparent substrate, a master, a stamp and/or a product, in particular an imprinted product, can be meant. The substrate is in particular an imprinted substrate or a substrate configured for imprinting. The substrate can for example be configured for use in a nano-imprint lithography transfer process. At least part of the substrate is preferably substantially transparent, or at least part of the substrate is substantially translucent. The substrate can also be intrinsically transparent, but have a non-transparent reflective layer on the interface that is facing away from the imaging device. Such a non-transparent reflective layer can for example comprise at least one metal, or such layer can be a metal coating layer. It is for example imaginable that that the substrate is at least transparent in the in-plane directions. At least one substrate can for example be at least partially made of glass, quartz and/or fused silica, polymers such as polycarbonate, PMMA, PET and/or any combination of these materials. It is imaginable that the substrate is substantially flexible. However, it is also possible that at least part of the substrate is substantially rigid. It is also imaginable that the substrate comprises a mounting structure. However, the device according to the invention also enables receiving of substrate which are free of any mounting structures. Optionally, the substrate comprises a textured area. The textured area can for example comprise a texture with dimension typically in the range from 500 micrometer down to 25 nanometer. The device according to the invention is in particular suitable for use in combination with relatively large substrates. The device can for example be configured for receiving a substrate having a surface area of at least 0.05 m2 , preferably at least 0.2 m2 , more preferably at least 0.5 m2 . However, it is imaginable that the substrate has a surface area up to 1 m2 . The thickness of at least one substrate is preferably at least 0.1 mm and/or at most 10 mm. It is also imaginable that the thickness of at least one substrate is in the range of 0.5 to 8 mm, in the range of 1 to 6 mm or in the range of 2 to 4 mm. The substrate preferably comprises a front surface, a back surface and at least one side edge. In case the substrate is substantially rectangular, it is conceivable that the substrate comprises at least one pair of opposing side edges and in particular two pairs of opposing side edges. The side edges of the substrate are preferably substantially plain and/or free of texture. The device according to the invention could also be referred to as an inspection device.

In a preferred embodiment, at least part of at least one light source is positioned within the housing. At least one light source is preferably positioned such that at least one light source is partially shielded by said housing. More in particular, at least part of one light source can be positioned within the housing wherein or such that at least one light source is shielded by said housing seen from a point where the imaging device is positioned for the (visual) substrate analysis. This embodiment enables that light emitted by the light source(s) will not illuminate in the direction of the imaging device directly and/or via reflection inside the housing and/or via reflection via the edge of the substrate, wherefore the imaging and/or analysis process will not be affected by said (primary) light source(s). It is preferred that also (side) edges of the substrate that are not directly illuminated by a light source are shieled by the housing, in particular since those edges can still scatter and/or refract light from any light that is internally reflected in the substrate. Hence, the housing may be configured to shield at least part of at least one side edge of the substrate, in particular part of at least one side edge which is not (directly) illuminated by the at least one light source. The housing can further provide a protective function for the light source. It is imaginable that at least part of at least one light source is attached to the housing, in particular to an edge of the housing. In this way, the positioning of the light source with respect to a substrate received in the housing can be further optimized. An optimized position of at least one light source will have a positive effect on the accuracy of the following imaging process and the analysis thereof.

At least one light source is preferably a LED light source. It can also be said that at least one light source comprises at least one light-emitting diode (LED) or multiple light-emitting diodes (LEDs). In yet another possible embodiment, at least one light source can comprise multiple light elements, wherein each light element is configured to emit light. At least one light source is preferably configured to emit light with a wavelength in the range of 275 to 950 nm. It is for example imaginable that at least one light source is configured to emit chosen from ultraviolet, (near) UV, (near) infrared and/or combination thereof. It is for example imaginable that at least one light source is configured to emit light with a wavelength in the range of 240 to 360 nm, in the range of 395 to 530 nm, in the range of 565 to 645 nm or in the range of 660 to 900 nm. Further preferred ranges can be wavelengths in the range of 450 to 475 nm and/or 520 to 530 nm. At least one light source can for example emit white, green, yellow, indigo, violet, red, blue, cyan and/or magenta, and/or combination thereof. The output of at least one light source is preferably at least 10 lm/cm. At least one light source is preferably configured to emit non collimated light. Hence, it is conceivable at least one light source is configured to spread out light in various directions and/or that at least one light source does not have a defined directionality.

In a possible embodiment, at least one light source is configured to emit polarized light. In another possible embodiment, the intensity of at least one light source can be modulated. In yet another possible embodiment, the emission pattern of at least one light source can be optimized for efficient coupling of light into the substrate.

It is imaginable that the device comprises multiple light sources. It is for example possible that the device comprises at least two light sources. However, it is also possible that the device comprises at least three or at least four light sources. At least one light source could optionally also comprise multiple light element, for example multiple LED's. At least one light source can for example be an elongated light source. At least one light source can for example comprise a strip light and/or a string light, for example a LED strip and/or a LED string or a LED array. It is possible that the device comprises at least two light sources, wherein at least two light sources are opposing each other. In a preferred embodiment, the device comprises at least two light sources are positioned in an opposing configuration wherein each light source is directed to at least one edge, in particular a side edge, of the substrate which is received within the housing. It is conceivable that the device comprises at least four light sources, or at least one light source comprising at least four sections, wherein each light source or section thereof is directed to at least one side edge of the substrate. Preferably, at least one light source, or multiple light sources are positioned such that said light source or said light sources substantially enclose at least one substrate received in the housing. Such embodiment can ensure a constant and homogeneous illumination of the substrate. It is imaginable that the device and in particular at least one light source comprises at least one edge light, wherein the edge light follows an inner surface of the edge of the housing.

At least one light source is optionally positioned at a distance from least one support surface. However, it is also conceivable that at least one light source is positioned upon at least one support surface. The preferred configuration can dependent on the type of substrate and the dimension thereof and on the type of light source applied. It is for example imaginable that the light source is in contact with the substrate. However, it is also possible that the lights source is positioned at a distance from the substrate during use, for example at a distance in the range of 0.02 to 2 cm, 0.05 to 1 cm, 0.1 to 0.5 cm or combinations thereof. It is preferred that at least one light source is positioned at an inner side of at least one edge of the housing. In this way, the edge of the housing can provide a supportive and/or protective function for the light source. At least one light source could optionally also form integrally part of the housing.

In a preferred embodiment, the device, and in particular the housing, comprises at least one shieling element, in particular at least one displaceable shielding element, configured for shielding at least part of the substrate and/or at least part of at least one light source. At least one shielding element can for example be configured to prevent undesired emission of light in a direction away from the substrate. At least one shielding element is preferably displaceably attached to the housing such that the shielding element is displaceable between an opened configuration and a closed configuration. The open configuration is preferably configured such that a substrate can be positioned within the device without deforming the substrate. The closed configuration is preferably configured such that the substrate is enclosed and/or embedded by the housing and/or at least one shielding element. It is beneficial if at least one shielding element is pivotably attached to at least part of the housing, in particular to at least part of at least one edge of the housing. A pivoting shielding element can provide a controlled displacement of the shielding element, in particular between an opened and a closed configuration. In case the device comprises multiple shielding elements, it is desired that at least two and preferably multiple shielding elements are pivotable. In a preferred embodiment, all shielding elements are pivotable. It is for example imaginable that at least one shielding element is attached to the housing, and in particular to at least one edge of the housing via at least one hinge. The shielding element(s) are preferably configured to be positioned at a distance from the receiving space of the housing wherein the substrate is to be received, in particular at least in the closed configuration, more in particular in the opened and the closed configuration. It is desired that the shielding element(s) cannot get into direct contact with the substrate. This could negatively affect the analyzing process or even cause damage to the substrate. The device, and in particular, could comprise at least one limiter to limit the displacement of at least one shielding element. At least one shielding element is preferably positioned at a distance from at least one support surface. This will reduce the risk of the shielding element getting into contact with a substrate positioned upon the support surface. In a beneficial embodiment, at least part of the shielding element absorbs light. It is for example imaginable that an inner side of at least one shielding element comprises a light absorbing material and/or a light absorbing color. It is for example imaginable that at least an inner side of at least one shielding element comprises a dark color, preferably back or a black derivative.

In a beneficial embodiment, at least part of at least one support surface absorbs light. It is for example imaginable that the support surface comprises a light absorbing material and/or a light absorbing color. It is for example imaginable that the support surface comprises a dark color, preferably back or a black derivative.

In a preferred embodiment, at least one support surface is positioned at a distance from at least one back cover. This embodiment can prevent that the back cover can get into direct contact with a substrate positioned upon the support surface. This is beneficial in order to prevent the back cover affecting the analysis process. It for example imaginable that at least part of at least one support surface is positioned substantially parallel to at least part of at least one back cover. In particular an inner surface of at least one back cover can be positioned substantially parallel to at least part of at least one support surface. It is for example possible that at least one back cover is attached to at least one edge of the housing. In this way, the combination of at least one back cover and at least one edge can form a protective casing for at least one substrate.

The back cover can provide a protective function in a constructive way, but also with respect to the illumination aspect. It is beneficial if a surface of at least one at least one back cover facing the back side of the substrate comprises at least one light absorbing color and/or at least one light absorbing material. It is beneficial if at least part of the back cover absorbs lights, as this will be beneficial for the accuracy of the analysis of the substrate. Reflection or transmission from the background behind the substrate could influence the images made of the substrate and could also further affect the analysis thereof. It is beneficial if the back cover, or at least the part thereof which overlaps with the substrate, comprises a single color. It is preferred that at least the part of the back cover facing the substrate has a uniform character. At least part of the back cover which overlaps with the substrate, and if present, the active area of the substrate, preferably has a uniform character, preferably wherein the active area is the region of the substrate which is textured or patterned by an imprinting process. It is possible that at least part of the back cover, for example a surface the back cover, facing the substrate, and in particular the back side of the substrate, comprises a dark color, preferably black, grey or a derivative thereof. A dark color can be classified as a color having a low lightness and/or a relatively low luminance. A preferred characteristic of a dark color is also that it absorbs light. Most preferably, at least part of the back cover facing the substrate is black.

The device according to the present invention could optionally comprise at least one control unit. At least one control unit can for example be configured to control at least one parameter of the light source. The control unit can for example be configured to control at least the intensity and/or wavelength of at least one light source. It is also imaginable that the device comprises at least one display. The display can be coupled with at least one control unit, if applied.

The device could further comprise at least one support structure. The support structure can for example be configured to position the housing, and thus the substrate received therein, in a predetermined position. The support structure can for example be configured to align the housing, and thus the support, with respect to an imaging device. In yet another embodiment, the device may comprise at least one enclosure. It is for example imaginable that the device comprises an enclosure wherein the housing and optionally at least one imaging device can be received. It is in particular beneficial if at least one enclosure is configured such that said enclosure provides a substantially dark environment. The inspection of the substrate can be further improved when environmental influences can be minimized.

The invention also relates to an assembly of at least one device according to the present invention and at least one imaging device. The imaging device can for example be a camera. It is also possible that at least one imaging device comprises at least one camera.

In a preferred embodiment, at least one imaging device is positioned at a predetermined distance from the device. It is for example possible that the assembly comprises at least one distance element configured for aligning at least one imaging device and the device according to the present invention. It is also imaginable that such distance element is configured for keeping at least one imaging device in a preferred configuration and distance with respect to the device according to the present invention.

The invention further relates to an imprinting system comprising at least one device or assembly according to the present invention. Such imprinting system is preferably configured for transferring at least one pattern and/or least one structure to at least one substrate, in particular at least one substantially transparent substrate. It is also imaginable that the system is configured for transferring at least one pattern and/or least one structure to at least one substrate, in particular at least one substantially transparent substrate. The device and/or assembly according to the present invention can for example form (integral) part of the imprinting system. It is for example conceivable that at least one device and/or assembly forms part of at least one input section and/or at least one output section of the imprinting system.

The invention further relates to a method for inspection of a substantially transparent substrate, comprising the steps of:
positioning at least one substrate, in particular at least one substantially transparent substrate, in a device according to the present invention;
illuminating at least part of at least one side edge of at least one substrate via at least one light source;
capturing at least one image of at least part of the substrate (to be inspected), in particular the illuminated substrate; and
analyzing at least one image upon defects via the detection of light-scattering elements.

The method can also be referred to as a method for detecting light-scattering elements on a substantially transparent substrate. The invention in practice relates to a method for detecting and labeling light-scattering elements on transparent substrates using a vision setup and/or software analysis. Any of the described embodiments of the device according to the invention also apply to the method according to the invention.

It is imaginable that at least one substrate is freely positioned within the housing of the device. Preferably, at least one substrate is (freely) positioned upon at least one support surface. Preferably, no clamping attachment is applied, as this could negatively affect the substrate as such but also the accuracy of the analysis of the substrate. It is imaginable that the housing is closed after placing of the substrate. Illuminating at least part of at least one side edge of at least one substrate is done via at least one light source. Any of the described light sources and configurations thereof can be applied. It is for example preferred that light is emitted to the substrate via at least two side edges thereof. It is also possible that light is emitted over substantially the entire length of each side edge of the substrate, in particular such that a uniform light pattern is created within the substrate. It is imaginable that at least part of the light source is in direct contact with a side edge of the substrate. However, it is also possible that an air gap, preferably smaller than 2 mm gap is applied between the light source and the substrate. At least one image of the (illuminated) substrate can be captured with at least one imaging device, for example a camera. Analysis of at least one image, and preferably of a series of images can be done in order to determine any defects and/or irregularities. These defects and/or irregularities can in particular be determined via the detection of light-scattering elements. The light-scattering elements can be classified upon relevance when analysis the quality of the substrate during the inspection. Hence, the method according to the invention provides the detection and labeling of light-scattering elements such as defects, contamination and other patterns on transparent substrates in a reproducible and reliable manner.

The substrate is preferably positioned in front of a light absorbing background, such as a light absorbing back cover according to the present invention. More preferably, the imaging is performed in a substantially dark environment. This could optionally be created by using an enclosure according to the present invention. The substrate is illuminated on from least one side edge by at least one light source, for example at least one LED array. Due the light source illumination at least one side edge of the substrate, due to internal reflection, the majority of the light is trapped inside the substrate and light will only escape at the edges of the substrate and/or at positions on the surface that contain light-scattering elements such as defects, contamination or other patterns. The use of a light absorbing background and/or a substantially dark environment enables that the light-scattering elements have a large contrast to the background. The contrast can for example be further enhanced by placing an opaque, black frame over the edges of the substrate, for example in the form of a shielding element. In case shielding element(s) are applied, these are preferably folded open to an opened configuration prior to inserting the substrate in the housing. A focused image of the substantially transparent substrate is made using a (visual) imaging device such as a camera or an optical sensor. The skilled person is aware of the optimal settings such as the focus, aperture, sensitivity and shutter speed which will result in good contrast of the light-scattering elements within the substrate with respect to the background.

The method could comprise the step of comparing correlated images obtained with the same substrate prior to and after one or multiple handling and/or imprinting steps and/or processing steps. This embodiment allows for tracking the evolution of defects, contamination and/or other patterns within a specific substrate. The method could also comprise the step of comparing correlated images obtained with different substrates that have been subjected to the same process step for example a pattern replication process. For example, different substrates can be studied that have been subjected to a pattern replication process that is executed with the same stamp, the same submaster or the same master. This embodiment allows for monitoring the evolution of defects during the process step, for example the replication process and identifying in which stage of the (replication) process a particular defect was introduced or removed. It is imaginable that at least one image processing algorithm is used to analyze the presence and/or absence of light-scattering elements of at least one image, for example a single image. The image processing algorithm can for example be configured to count the number of light-scattering element(s) and/or to provide coordinates of the (identified) light-scattering element(s). The image processing algorithm could also be configured to classify the detected light-scattering elements. Preferably, one or more additional images are taken of either the same substrate after subjecting it to a process that is to be studied, or of another substrate that has undergone a similar pattern replication process as the initial substrate. It is imaginable that a series of images is produced and analyzed for the abovementioned embodiments. The images are preferably analyzed upon the presence and/or absence of light-scattering elements. The detected light-scattering elements can subsequently be classified. It is for example imaginable that at least one image processing algorithm is used to analyze the light-scattering elements, for example the presence and/or absence of light-scattering images. Preferably, at least one image processing algorithm comprises image arithmetic to detect similarities and differences between at least two correlated images. The method could further comprise the step of providing a comparative image wherein deviations between at least two images are depicted. Such comparative image can be used to count, label and/or provide coordinates of the detected light-scattering elements. The method according to the present invention can be applied during any interval of an overall imprinting process. Typically, the transparent substrate is subjected to a (sub)process that is to be studied. Examples of (sub)processes that can be studied are handling processes, cleaning processes, coating or imprinting processes.

Optionally, a wiping or cleaning step can be performed on the back side of the substantially transparent substrate to remove or displace backside contamination prior to the analysis. At least one additional image per substrate can be taken and can for example be used to distinguish light-scattering elements on the back side of the substrate from elements on the front side. When using image processing algorithms, the following optional actions can be performed in various orders converting colored images to gray scale to increase the processing speed and precision, enhancing the contrast of the images, and/or aligning at least two images with each other to correct small misalignments in translation, rotation and/or perspective. To help with the aligning process, two or more markers can be used on the transparent substrate and/or the working stamp or submaster that was used to create the replicated substrates. Further optional actions can be performed using image processing algorithms: cropping of the images to select the areas of interest, dilation of the pixels in the image to enlarge the surface area of imaged scattering elements in the images, comparing at least two images with each other using image arithmetic. In order to detect similarities between the images, a new image can be constructed that is the (normalized) product of two or more images. The resulting image now contains only elements that are present in all of the multiplied images. To detect differences between a pair of images, new images can be constructed by subtracting one image from the other. Optionally, a scalar can be added to all the pixel values so that otherwise negative pixel values can be displayed. An alternative method to detect differences between two or more images is to divide the images by each other. Sequences containing multiple of arithmetic operations that are described above can be used depending on the specific use case. The resulting comparative images can used to label the light-scattering elements in the image. In order to do this, further image processing steps can be performed such as enhancing the contrast of the resulting image, binarization of the resulting image using a specific threshold, counting the amount of individual detected elements or groups of elements that are in close proximity to each other, listing the coordinates of detected elements or element groups and/or labeling the detected elements using text or (colored) visual aids in the image. Any of the described optional steps can be included in the method according to the present invention.

The invention will be further elucidated by means of the following non-limitative clauses.
1. Device for enabling inspection of a substantially transparent substrate, comprising:
   at least one housing configured for receiving at least one substantially transparent substrate, said housing comprising:
      at least one edge for surrounding at least part of the substrate;
      at least one support surface for supporting at least part of the substrate;
      at least one back cover for covering at least part of the substrate;
   at least one light source configured for illumination at least part of the substrate; wherein at least one light source is positioned at least partially within the housing such that at least one light source is directed to at least one side edge of the substrate which is received within the housing, in particular such that at least part of the light emitted by at least one light source enters the substrate via at least one side edge such that the light can propagate through the substrate.
2. Device according to clause 1, wherein at least part of at least one light source is positioned within the housing such that at least one light source is partially shielded by said housing.
3. Device according to any of the previous clauses, wherein at least part of at least one light source is attached to the housing.
4. Device according to any of the previous clauses, wherein at least one light source is a LED light source.
5. Device according to any of the previous clauses, wherein at least two light sources are positioned in an opposing configuration wherein each light source is directed to at least one side edge of the substrate which is received within the housing.
6. Device according to any of the previous clauses, wherein at least one light source, or multiple light sources are positioned such that said light source or said light sources enclose at least one substrate received in the housing.
7. Device according to any of the previous clauses, wherein at least one light source is positioned at a distance from least one support surface.
8. Device according to any of the previous clauses, wherein at least one light source is positioned upon at least one support surface.
9. Device according to any of the previous clauses, wherein at least one light source is positioned at an inner side of at least one edge of the housing.
10. Device according to any of the previous clauses, comprising at least one shieling element, in particular at least one displaceable shielding element, configured for shielding at least part of the substrate and/or at least part of at least one light source.
11. Device according to clause 10, wherein at least one shielding element is pivotably attached to at least part of the housing, in particular to at least part of at least one edge of the housing.
12. Device according to clause 10 or clause 11, wherein at least one shielding element is positioned at a distance from at least one support surface.
13. Device according to any of the previous clauses, wherein at least one support surface is positioned at a distance from at least one back cover.
14. Device according to any of the previous clauses, wherein at least one support surface is positioned substantially parallel to at least part of at least one back cover.
15. Device according to any of the previous clauses, wherein at least part of at least one back cover facing the substrate comprises at least one light absorbing color and/or at least one light absorbing material.
16. Device according to any of the previous clauses, wherein at least part of at least one back cover facing the substrate comprises a dark color, preferably black or a derivative thereof.
17. Device according to any of the previous clauses, comprising at least one control unit for controlling at least one parameter of at least one light source.
18. Device according to any of the previous clauses, comprising at least one enclosure.
19. Assembly of at least one device according to any of the previous clauses and at least one imaging device.
20. Imprinting system comprising at least one device according to any of clauses 1 to 18 or at least one assembly according to clause 19, preferably wherein said imprinting system is configured for transferring at least one pattern and/or least one structure to at least one substrate, in particular at least one substantially transparent substrate.
21. Method for inspection of a substantially transparent substrate, comprising the steps of:
   positioning at least one substrate, in particular at least one substantially transparent substrate in a device according to any of clauses 1 to 18;
   illuminating at least part of at least one side edge of the substrate via at least one light source;
   capturing at least one image of at least part of the substrate to be inspected; and
   analyzing at least one image upon defects via the detection of light-scattering elements.
22. Method according to clause 21, wherein at least one substrate is positioned upon at least one support surface.
23. Method according to clause 21 or clause 22, wherein at least one image processing algorithm is used to analyze the presence and/or absence of light-scattering elements of at least one image.
24. Method according to any of clauses 21 to 23, comprising the step of comparing correlated images obtained with the same substrate prior to and after one or multiple handling and/or processing and/or imprinting steps.
25. Method according to any of clauses 21 to 24, comprising the step of comparing correlated images obtained with different substrates that have been subjected to the same process step.
26. Method according to clause 24 and/or clause 25, wherein the images are analyzed upon the presence and/or absence of light-scattering elements.
27. Method according to any of clauses 24 to 26, wherein at least one image processing algorithm is used to analyze the light-scattering elements, and wherein at least one image processing algorithm comprises image arithmetic to detect similarities and differences between at least two correlated images.
28. Method according to any of clauses 21 to 27, comprising the step of providing a comparative image wherein deviations between at least two images are depicted.
29. Method according to any of clauses 21 to 28, comprising the step of counting the number of light-scattering element, providing coordinates of the light-scattering element and/or classifying of the light-scattering elements.

### BRIEF DESCRIPTION OF THE DRAWINGS

The terms Fig., Figs., Figure, and Figures are used interchangeably in the specification to refer to the corresponding figures in the drawings.

The invention will be further elucidated by means of non-limiting exemplary embodiments illustrated in the following figures, in which:

FIG. 1 shows a first possible embodiment of a device according to the present invention;

FIG. 2 shows a schematic, cross sectional view of another possible embodiment of a device according to the present invention;

FIGS. 3a and 3b show a detailed view of part of FIG. 2 wherein the effect of a defect upon the substrate is shown; and

FIG. 4 shows a further possible example of a device according to the present invention.

Within these figures, similar reference numbers correspond to similar or equivalent elements or features.

### DESCRIPTION OF THE INVENTION

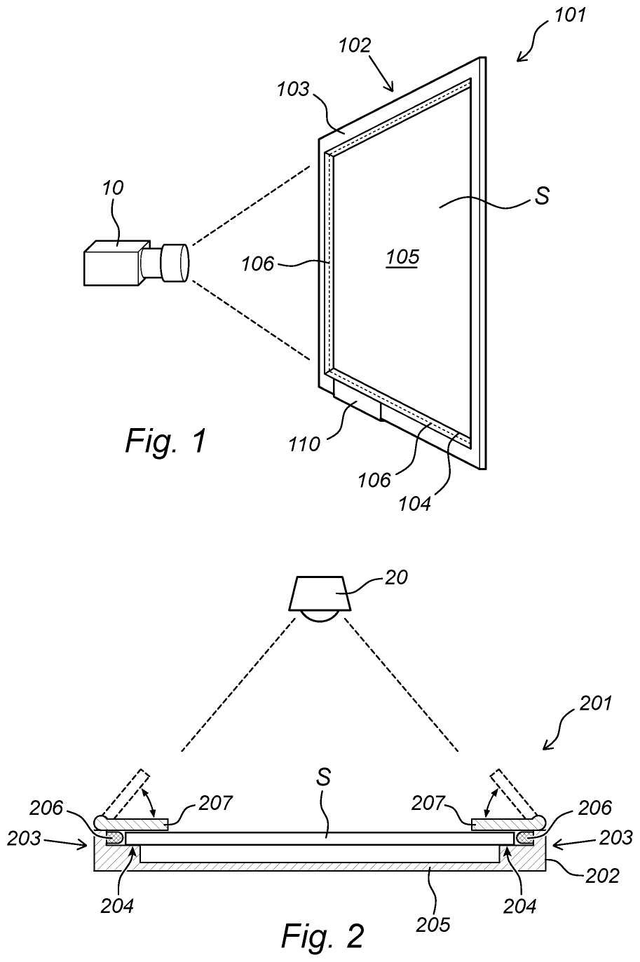

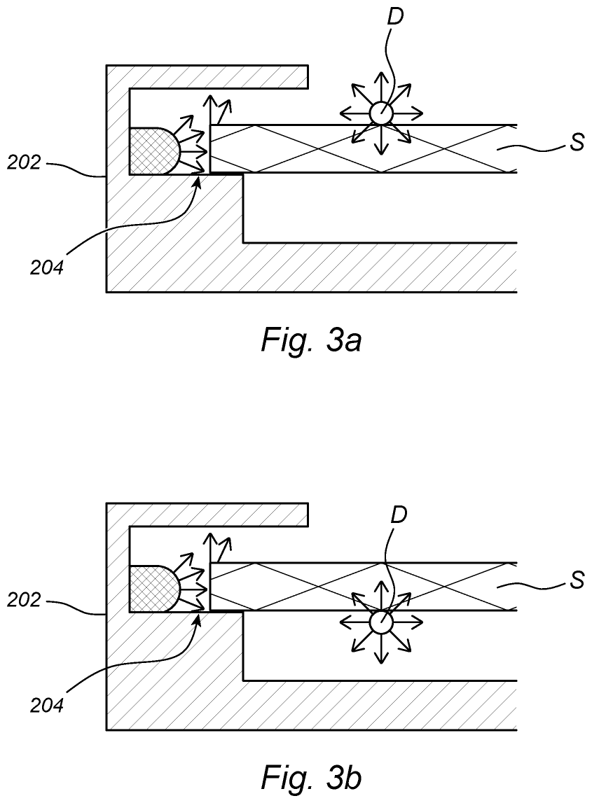

FIG. 1 shows a schematic and perspective view of first possible embodiment of a device 101 according to the present invention. The figure in particular shows an assembly according to the present invention comprising a device 101 according to the present invention and an imaging device 10. The device 101 is a tool configured for enabling efficient inspection of a substrate (S). The device 101 comprises thereto a housing 102 which comprises at least one edge 103 for surrounding at least part of the substrate S, at least one support surface 104 for supporting at least part of the substrate S and a back cover 105 for covering at least part of the substrate S. In the shown perspective view, the back cover 105 is positioned behind the substrate S. The preferred position of the substrate S within the housing 101 can be seen in more detail in FIGS. 2, 3a and 3b. The device 101 further comprises at least one light source 106. In the shown embodiment, the light source 106 substantially encloses the substrate S. The light source 106 is configured for illumination the substrate S and is thereto positioned at least partially within the housing 101 such that the light source 106 is directed to at least one edge of the substrate S which is received within the housing 101. The light source 106 is positioned such that light elements of the light source 106 oppose each other on each side of the substrate S. The device 101 further comprises a display 110.

The figure shows that the imaging device 10, in particular the camera 10, is poisoned at a distance from the device 101, and thus from the substrate S received therein.

FIG. 2 shows a schematic cross sectional view of another possible embodiment of a device 201 according to the present invention. The device 201 comprises a housing 202 configured for receiving a substrate S. The housing 202 comprises an edge 203, a support surface 204 and a back cover 205. The edge 203 of the housing 202 is configured for surrounding at least part of the substrate S. The support surface 204 is configured for supporting at least part of the substrate S and in particular the circumference thereof. The cross-sectional view further shows that a back cover 205 which covers at least part of the substrate S. The device 201 further comprises light sources 206 configured for illumination at least part of the substrate S. The light sources 206 are positioned at least partially within the housing 202 such that light emitted by the light sources 206 is directed to an edge, in particular a side edge, of the substrate S which is received within the housing 202. It can be seen that the light sources 206 are shielded by the housing 202. Additionally, the light sources 206 are shielded by shieling elements 207. The shielding elements 207 are displaceable with respect to the edge 203 of the housing 202. The figure illustrates that the shielding elements 207 are pivotably attached to the housing 202, in particular an edge 203 of the housing 203. The shielding element 207 cover, or shield the light sources 206 with respect to the imaging device 20. The pivotable character of the shielding elements 207 is beneficial for the ease of the device 201, since the shielding elements 207 can be pivoted away from the support surfaces 204 such that the substrate S can be easily positioned upon the surface(s) 204 without being affected by the shielding elements 207. The shielding elements 207 are positioned at a distance from the support surface(s) 204. In the shown embodiment, the light sources 206 are positioned adjacent to the support surfaces 204. In this way, the transfer of light from the light sources 206 to the substrate S is fully optimized. The imaging device 20 is for example a camera 20. The imaging device 20 is positioned at a predetermined distance from the substrate S. In the shown embodiment, the light sources 206 are shielded by the housing 202, and in particular by the shielding elements 207 such that the imaging device 20 is not affected by light emitted from the light sources 206. The substrate S is positioned substantially parallel to the back cover 205. The back cover 205 of the shown embodiment has a dark and uniform color, and the back cover 205 covers the back surface of the substrate S fully. The light sources 206 are positioned such that the light is directed to the side edges of the substrate S. The light sources 206 are thereby are in particular positioned at an inner side of the edge 203 of the frame 202.

FIGS. 3a and 3b show a detailed view of part of FIG. 2, wherein the effect of a defect D upon the substrate S is shown. The defect D acts as a light-scattering element. FIG. 3a shows the effect of the light scattering via the defect D upon the upper surface of the substrate S, where FIG. 3b shows the same effect for a defect D on the bottom surface of the substrate S. The substrate S is received in a housing 202 wherein the substrate S is positioned upon a support surface 204.

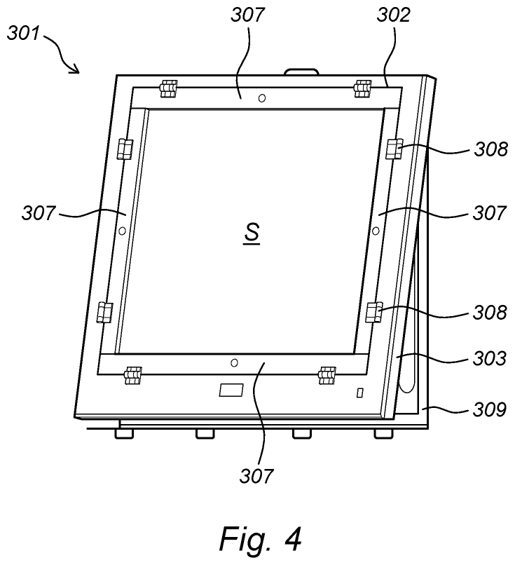

FIG. 4 shows a further possible example of a device 301 according to the present invention. The figure shows a perspective view of the device 301 comprising a housing 302 configured for receiving a substrate S. The housing 302 comprises an edge 303, a support surface (not shown) and a back cover positioned behind the substrate. The edge 303 of the housing 302 surrounds the substrate S. The substrate S is further shielded by hingedly connected shielding elements 307. The shieling elements 307 are connected to the housing 302 via hinges 308. The device 301 further comprises a support structure 309 upon which the housing 302 is positioned.

It will be clear that the invention is not limited to the exemplary embodiments which are illustrated and described here, but that countless variants are possible within the framework of the attached claims, which will be obvious to the person skilled in the art. In this case, it is conceivable for different inventive concepts and/or technical measures of the above-described variant embodiments to be completely or partly combined without departing from the inventive idea described herein.

The verb ‘comprise’ and its conjugations as used in this patent document are understood to mean not only ‘comprise’, but to also include the expressions ‘contain’, ‘substantially contain’, ‘formed by’ and conjugations thereof.

1. A device for enabling inspection of a substantially transparent substrate, comprising:
at least one housing configured for receiving at least one substantially transparent substrate, said housing comprising:
at least one edge for surrounding at least part of the substrate;
at least one support surface for supporting at least part of the substrate;
at least one back cover for covering at least part of the substrate;
at least one light source configured for illumination at least part of the substrate;
wherein at least part of the at least one light source is positioned within the housing wherein the at least one light source is partially shielded by the housing and wherein the at least one light source is directed to at least one side edge of the substrate which is received within the housing such that at least part of the light emitted by at least one light source enters the substrate via at least one side edge such that the light can propagate through the substrate.

2. The device according to claim 1, wherein the housing comprises at least one receiving space which is defined by at least part of at least one support surface and at least one edge of the housing, and wherein at least one light source is received within the receiving space.

3. The device according to claim 1, wherein at least part of at least one light source is attached to the housing.

4. The device according to claim 1, wherein at least one light source is a LED light source.

5. The device according to claim 1, wherein at least two light sources are positioned in an opposing configuration wherein each light source is directed to at least one side edge of the substrate which is received within the housing.

6. The device according to claim 1, wherein at least one light source, or multiple light sources are positioned such that said light source or said light sources enclose at least one substrate received in the housing.

7. The device according to claim 1, wherein at least one light source is configured to emit non collimated light.

8. The device according to claim 1, wherein at least one light source is positioned at a distance from least one support surface.

9. The device according to a claim 1, wherein at least one light source is positioned upon at least one support surface and/or wherein at least one light source is positioned at an inner side of at least one edge of the housing.

10. The device according to claim 1, comprising at least one shielding element configured for shielding at least part of the substrate and/or at least part of at least one light source.

11-12. (canceled)

13. The device according to claim 1, wherein at least one support surface is positioned at a distance from at least one back cover and/or wherein at least one support surface is positioned substantially parallel to at least part of at least one back cover.

14. (canceled)

15. The device according to claim 1, wherein at least part of at least one back cover facing the substrate comprises at least one light absorbing color and/or at least one light absorbing material and/or wherein at least part of at least one back cover facing the substrate comprises a dark color.

16-18. (canceled)

19. An assembly of at least one device according to claim 1 and at least one imaging device.

20. An imprinting system comprising at least one device or assembly according to claim 1.

21. A method for inspection of a substantially transparent substrate, comprising the steps of:
positioning at least one substrate in a device according to claim 1;
illuminating at least part of at least one side edge of the substrate via at least one light source;
capturing at least one image of at least part of the substrate to be inspected; and
analyzing at least one image upon defects via the detection of light-scattering elements,
wherein at least one image processing algorithm is used to analyze the presence and/or absence of light-scattering elements of at least one image.

22. The method according to claim 21, wherein at least one substrate is positioned upon at least one support surface.

23. The method according to claim 21, wherein at least one image processing algorithm is configured to count the number of light-scattering elements and/or to provide coordinates of the identified light-scattering elements.

24. The method according to claim 21, comprising the step of comparing correlated images obtained with the same substrate prior to and after one or multiple handling and/or processing and/or imprinting steps and/or comprising the step of comparing correlated images obtained with different substrates that have been subjected to the same process step.

25-27. (canceled)

28. The method according to claim 21, comprising the step of providing a comparative image wherein deviations between at least two images are depicted.

29. The method according to claim 21, comprising the step of counting the number of light-scattering element, providing coordinates of the light-scattering element and/or classifying of the light-scattering elements.
